(19) United States
(12) Patent Application Publication
(10) Pub. No.: US 2012/0020379 A1
(43) Pub. Date: Jan. 26, 2012

(54) SEMICONDUCTOR LASER MODULE AND SUPPRESSION MEMBER

(75) Inventors: Kengo Muranushi, Tokyo (JP); Toshio Kimura, Tokyo (JP); Toshikazu Mukaihara, Tokyo (JP)

(73) Assignee: FURUKAWA ELECTRIC CO., LTD., Tokyo (JP)

(21) Appl. No.: 13/260,527

(22) PCT Filed: Sep. 30, 2009
(86) PCT No.: PCT/JP2009/067050

§ 371 Date: Sep. 26, 2011

(30) Foreign Application Priority Data
Mar. 26, 2009 (JP) 2009-077446

(51) Int. Cl. H01S 5/024; H01S 5/022

(52) U.S. Cl. 372/34

(57) ABSTRACT

Above a Peltier element disposed on a bottom of a case, bases that are platy members of two or more layers and have different expansion coefficients from each other are stacked. At least on a partial region of the base serving as an uppermost layer, a suppression member having an expansion coefficient different from that of the base serving as the uppermost layer is further provided. An optical element is disposed on the base and/or the suppression member. Even when a warp is likely to occur in the Peltier element, a stacked-plate structure of the base, the base, and the suppression member suppresses an occurrence of such a warp, whereby warps hardly occur in the base and the suppression member, and a shift hardly occurs in an optical axis between a beam splitter and an etalon.

### FIELD

The present invention relates to a semiconductor laser module and a suppression member that can suppress a variation of a locking wavelength by suppressing an optical axis shift.

### BACKGROUND

A semiconductor laser module includes many components such as a semiconductor laser element, a condensing lens, a light detector that monitors output light, a temperature control element such as a Peltier element, and an isolator. The semiconductor laser module condenses output light from the semiconductor laser element with the condensing lens so as to be collimated light, and thereafter guides the collimated light to an optical fiber through the isolator so that the light is waveguided in the optical fiber to be provided for a desired application.

In the semiconductor laser module, because an optical path is formed with many components from the semiconductor laser element to the optical fiber, an optical axis, particularly an optical axis between the condensing lens and the isolator, needs to be exactly adjusted. If an optical axis shift occurs, for example, light output from the condensing lens receives vignetting by part of the isolator, causing light coupling efficiency to lower. Therefore, in some semiconductor laser modules, a lens holder holding a condensing lens and an isolator are fixedly disposed on a common fixing member (refer to Patent Literature 1).

### CITATION LIST

### Patent Literature

Patent Literature 1: Japanese Patent Application Laid-open No. 2001-194563

### SUMMARY

### Technical Problem

An example of an effect of the optical axis shift can be described as follows. In a semiconductor laser module, a beam splitter is provided on an optical axis from a condensing lens to an optical fiber. The beam splitter branches part of laser light. A wavelength filter such as an etalon filters the branched light. A light detector monitors light power having a filtered wavelength, so that wavelength locking control is performed.

In this regard, if a shift occurs in an optical axis from the beam splitter to the etalon, wavelength locking control cannot be performed with high accuracy. Particularly, a warp occurs along a horizontal direction in a Peltier element that is disposed at the bottom of the semiconductor laser module as a temperature control element because a temperature difference occurs between an upper portion and a lower portion of the Peltier element. The warp causes an optical axis shift to occur in a monitor optical axis. In this case, even though the beam splitter and the etalon are disposed on a common fixing member, there can occur a warp due to a difference in a linear expansion coefficient between the Peltier element and the fixing member, a warp due to a temperature distribution of the fixing member, and furthermore a warp due to a difference in a linear expansion coefficient among layers when the fixing member is composed of the layers of a plurality of materials. As a result, a large optical axis shift occurs. If the optical axis shift occurs in the optical axis of the light reflected by the beam splitter, the shift angle of the beam splitter results in an optical axis shift having a double shift angle.

FIG. 11 is a schematic illustrating a relationship of a wavelength shift amount to an optical axis angle where an optical axis angle is 0° when the optical axis is perpendicular to an input surface of an etalon. In FIG. 11, the wavelength shift amount is not large when the optical axis angle is small. However, as the optical axis angle becomes larger, the wavelength shift amount increases beyond the proportional relationship. For example, the wavelength shift amount is −200 pm when the initial angle of the etalon is 1.4°. If an angle shift of 0.2° occurs, the shift results in a large wavelength shift amount of 100 pm. As a result, wavelength locking control cannot be performed within an allowable range.

The present invention is made in view of the above and aims to provide a semiconductor laser module and a suppression member that can suppress a warp of a fixing member disposed on a temperature control element and suppress a shift of the optical axis of an optical path formed between optical elements disposed on an upper surface of the fixing member.

### Solution to Problem

To solve the problems and to attain the object, there is provided a semiconductor laser module according to the present invention, in which a plurality of optical elements optically coupled with each other are disposed on an upper surface of a temperature control element through at least one base, the semiconductor laser module including: a suppression member that is disposed, in order to suppress a deformation caused by a temperature change of the at least one base, on at least part of a deformation part of the at least one base, and has a linear expansion coefficient having a magnitude compensating for a linear expansion coefficient of the at least one base in order to suppress the deformation of the at least one base.

There is provided the semiconductor laser module according to the present invention, in which the at least one base includes a first base on which a semiconductor laser element is mounted, and a second base on which at least one of the optical elements is mounted and that is stacked on the first base, and the suppression member is disposed on a surface of the first base and/or the second base.

There is provided the semiconductor laser module according to the present invention, in which a magnitude relationship between a linear expansion coefficient of the first base and a linear expansion coefficient of the second base, and a magnitude relationship between the linear expansion coefficient of the second base and a linear expansion coefficient of the suppression member have a reverse relationship with each other.

There is provided the semiconductor laser module according to the present invention, in which a product of the linear expansion coefficient of the first base and a layer thickness of the first base is nearly equal to or smaller than a product of the linear expansion coefficient of the suppression member disposed on the second base and a layer thickness of the suppression member.

There is provided the semiconductor laser module according to the present invention, in which the suppression member is disposed on a surface on which the optical elements are absent, and has a shape suppressing the deformation.

There is provided the semiconductor laser module according to the present invention, in which an end on which the optical element(s) is (are) fixed of the second base is mounted on the first base as a cantilever structure.

There is provided a semiconductor laser module according to the present invention, in which a plurality of optical elements are disposed on an upper surface of a temperature control element through a plurality of bases, in which at least one of the plurality of bases is a suppression layer that has a linear expansion coefficient suppressing a deformation of another base other than the at least one of the plurality of bases in order to suppress the deformation of the other base due to a linear expansion coefficient difference associated with a temperature change of the other base.

There is provided the semiconductor laser module according to the present invention, in which, on surfaces of the plurality of bases, suppression members suppressing deformations due to a temperature change of the plurality of bases are disposed.

There is provided the semiconductor laser module according to the present invention, in which the temperature control element and a base on the temperature control element come in contact with each other at only around a central part thereof.

There is provided the semiconductor laser module according to the present invention, in which, on an upper surface of the suppression member, an optical element is further disposed.

There is provided the semiconductor laser module according to the present invention, in which, on an upper surface of the suppression member, a heat dissipation structure is provided.

There is provided a suppression member according to the present invention, suppressing a warp of a base that warps by a temperature change, in which the suppression member suppresses the warp of the base by compensating a difference in a linear expansion coefficient of the base.

### Advantageous Effects of Invention

When the base is placed on the temperature control element disposed on the bottom, a warp produced due to a difference in the linear expansion coefficient between the temperature control element and the base and a warp of the base due to the temperature distribution occur, or when a base is used that is composed of a plurality of platy members having different linear expansion coefficients and stacked on the temperature control element as two or more layers, a warp occurs in the stacked-plate of the base due to differences among the linear expansion coefficients. However, according to the present invention, by further providing the suppression member to suppress a warp on the bases, or inserting the suppression layer to suppress a warp into a stacked-plate structure, this warp suppression structure suppresses a warp of the base on the temperature control element even if such a warp is likely to occur, whereby a shift of an optical axis between optical elements can be prevented.

### BRIEF DESCRIPTION OF DRAWINGS

FIG. 1 is a perspective view illustrating a structure of a semiconductor laser module of a first embodiment of the present invention.

FIG. 2 is a schematic illustrating a longitudinal sectional view of the semiconductor laser module illustrated in FIG. 1 when viewed from a diagonal direction.

FIG. 3 is a longitudinal sectional view of the semiconductor laser module illustrated in FIG. 1.

FIG. 4 is a longitudinal sectional view illustrating a structure of a modified example of the semiconductor laser module illustrated in FIG. 1.

FIG. 5 is a schematic illustrating a longitudinal sectional view of a semiconductor laser module of a second embodiment of the present invention when viewed from a diagonal direction.

FIG. 6 is a longitudinal sectional view of the semiconductor laser module illustrated in FIG. 5.

FIG. 7 is a longitudinal sectional view illustrating a structure of a modified example of the semiconductor laser module illustrated in FIG. 5.

FIG. 8 is a longitudinal sectional view illustrating a comparative example 1 corresponding to the first embodiment of the present invention.

FIG. 9 is a longitudinal sectional view illustrating a comparative example 2 corresponding to the second embodiment of the present invention.

FIG. 10 is a schematic illustrating Y direction position dependency of a Z direction displacement amount of each of a conventional example, the comparative example 1, and the comparative example 2.

FIG. 11 is a schematic illustrating a relationship of a wavelength shift amount to an optical axis angle.

### DESCRIPTION OF EMBODIMENTS

Generally, a member having high stiffness is used to suppress a warp. However, when a warp occurs due to a temperature change, such a member simply having high stiffness may cause even a larger warp depending on the magnitude of the linear expansion coefficient of the member. The inventors of the present invention have found that a warp can be effectively suppressed by examining linear expansion coefficients of warping members for suppressing a warp due to a temperature change and using a member having a linear expansion coefficient capable of compensating the difference between the linear expansion coefficients of the members as a suppression member. The present invention is based on this finding. Preferred embodiments of a semiconductor laser module and a suppression member according to the present invention are described below in detail with reference to the accompanying drawings. The present invention, however, is not limited by the embodiments.

### First Embodiment

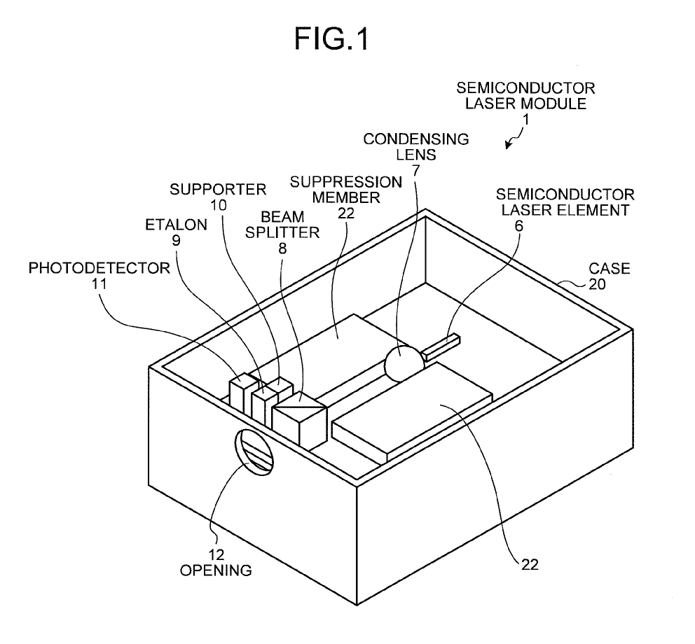

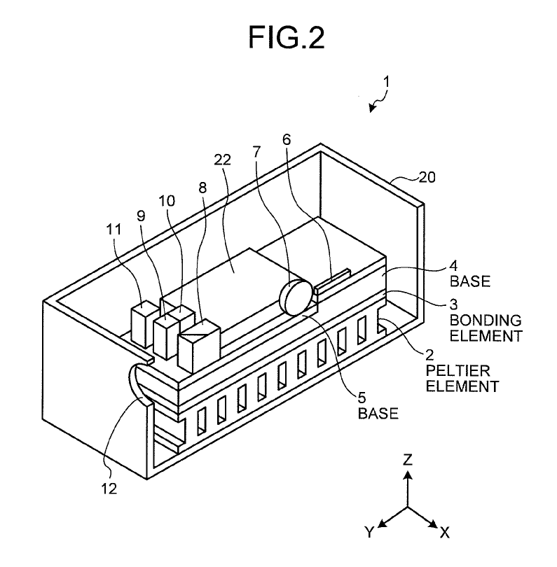

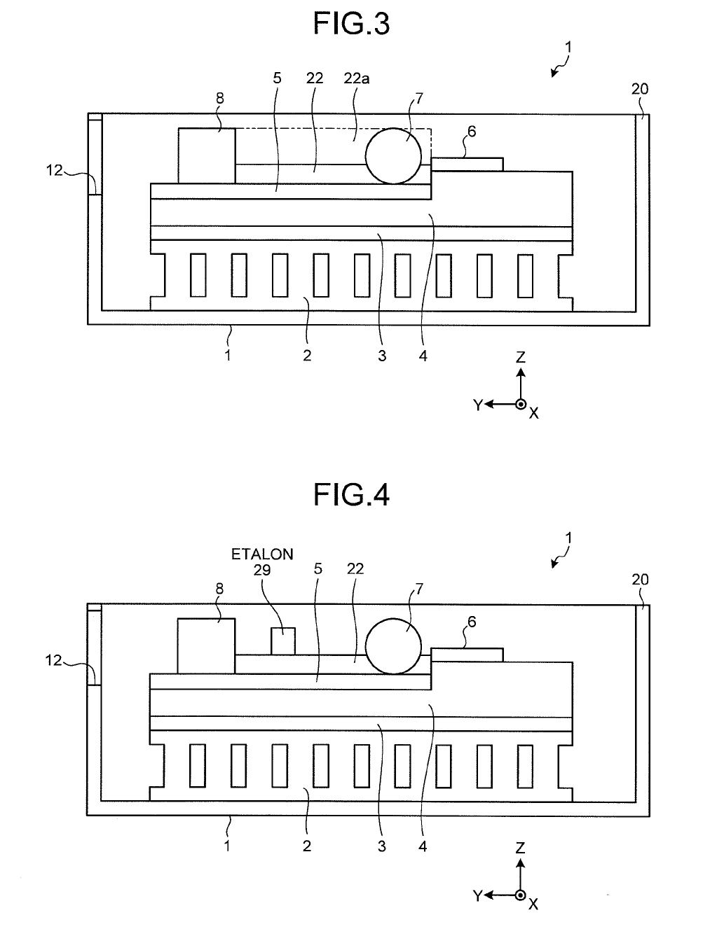

FIG. 1 is a perspective view illustrating a structure of a semiconductor laser module of a first embodiment of the present invention. FIG. 2 is a schematic illustrating a longitudinal sectional view of the semiconductor laser module illustrated in FIG. 1 when viewed from a diagonal direction. FIG. 3 is a longitudinal sectional view of the semiconductor laser module illustrated in FIG. 1. In FIGS. 1 to 3, in a semiconductor laser module 1, a Peltier element 2 serving as a temperature control element is fixedly disposed on the bottom of a case 20. On the entire upper surface of the Peltier element 2, a bonding member 3 made of alumina is bonded. Furthermore, on the entire upper surface of the bonding member 3, a base 4 that is made of copper-tungsten and has a platy shape is bonded. At one end in a longitudinal direction of the base 4, a stepped portion is formed. On the stepped portion, a semiconductor laser element 6 is disposed.

On a region of the base 4 excluding the stepped portion, a base 5 that is made of FeNiCo alloy, such as Kovar (registered trade mark), and has a platy shape is disposed. On the upper surface of the base 5, a condensing lens 7 that condenses laser light output from the semiconductor laser element 6 and converts the laser light into collimated light, a beam splitter 8 that has an isolator function with respect to the collimated light and branches part of collimated light, an etalon 9 that performs wavelength filtering on light brunched by the beam splitter 8, a supporter 10 that supports the etalon 9, and a light detector 11 that detects light after wavelength filtering performed by the etalon 9 are mounted. In addition, on a region on the upper surface of the base 5 excluding a region on which the condensing lens 7, the beam splitter 8, the etalon 9, the supporter 10, and the light detector 11 are mounted, a suppression member 22 that is made of alumina and has a platy shape is provided. A ferrule for fixing such as an optical fiber, and the like are inserted in an opening 12.

Here, the base 4, the base 5, and the suppression member 22 are platy members that have different linear expansion coefficients from one another. For example, the linear expansion coefficient of copper-tungsten of the base 4 is 6.65×10⁻⁰⁶(/° C.), that of FeNiCo alloy of the base 5 is 4.85×10⁻⁶ (/° C.), and that of alumina of the suppression member 22 is 7.20×10⁻⁶ (1° C.). The bordering platy members have different linear expansion coefficients from each other. The platy members are stacked so as to form a stacked-plate structure. A material of each layer preferably has high shear strength. The material of the suppression member needs to have a linear expansion coefficient that compensates for the linear expansion coefficients of the other layers, and more preferably has high stiffness. In a conventional case where the suppression member 22 is not included, a warp occurs because the linear expansion coefficient of the base 5 is smaller than that of the base 4. However, according to the present invention, alumina having the linear expansion coefficient larger than that of FeNiCo alloy (Kovar) is provided as the suppression member on the base 5 made of FeNiCo alloy (Kovar), resulting in the linear expansion coefficient differences at upper and lower of the base 5 being balanced. Consequently, a warp is eliminated. Magnitude of the linear expansion coefficients depends on materials of the bases. For example, platy members may be layered in such a manner that the platy members for the base 4, the base 5, and the suppression member 22 have large, small, and large expansion coefficients respectively. Alternatively, platy members may be layered in such a manner that the platy members for the base 4, the base 5, and the suppression member 22 have small, large, and small expansion coefficients respectively. In addition, when the stacked-plate structure is composed of a plurality of layers, the layers may have a relationship that each thermal expansion coefficient is compensated for each other. An action arises in each of the platy members to mutually offset and depress a warp. Even if a warp occurs in the Peltier element 2 including the bonding member 3, a warp hardly occurs in the base 5 and/or the suppression member 22, whereby a shift of an optical axis between the beam splitter 8 and the etalon 9 hardly occurs. The suppression member 22 may be selected so as to not only suppress a warp due to thermal expansion of the base 4 and the base 5 as described above, but also compensate for a warp produced by the Peltier element 2, the bonding member 3, the base 4, and the base 5. Consequently, wavelength locking control can be performed with high accuracy. The suppression member 22, in relation to a two-layer structure composed of only the base 4 and the base 5, can be disposed in an area where an optical element such as the beam splitter 8 is not disposed on the base 5. In order to suppress a warp of a portion on which the suppression member 22 is not disposed, a shape corresponding to a temperature distribution on a base may be employed in such a manner that the suppression member 22 imparts a large suppression effect.

Here, the thicknesses of the base 4, the base 5, and the suppression member 22 are determined based on bonding states and expansion coefficients among the platy members. In other words, the thicknesses are set in such a manner that a product of a volume of contact surfaces between bordering platy members and the linear expansion coefficient is nearly equal. As simplified, the thicknesses may be set in such a manner that a product of the thickness and the linear expansion coefficient of a stacked-plate structure of a portion on which the suppression member 22 is disposed, and a product of the thickness and the linear expansion coefficient of the suppression member 22 come close to each other, or the product relating to the suppression member is slightly smaller. Because of the setting, for example, as illustrated in FIG. 3, when a linear expansion coefficient of the suppression member 22 is smaller than a linear expansion coefficient of the base 4, it is preferable that a suppression member 22a having a thickness thicker than the thickness of the suppression member 22 be used.

Each platy member of the base 4, the base 5, and the suppression member 22 may be further formed as a platy member composed of a plurality of layers. In this case, the expansion coefficients may be nearly equal to one another. In short, platy members having different linear expansion coefficients from one another may be layered in three or more layers including the suppression member 22 in such a manner that the platy members compensate for a warp one another. In this regard, a layer to compensate for a warp may be additionally inserted into a platy structure. Furthermore, even if a base is formed in a single layer, the suppression member 22 of the present invention can suppress a warp by being provided on the surface of the base when the warp occurs due to a thermal distribution of the base.

As illustrated in FIG. 4, an optical element such as an etalon 29 is not limited to be mounted on the base 5 but also may be mounted on the suppression member 22. In addition, all of the optical elements may be mounted on the suppression member 22. Furthermore, a heat dissipation structure may be provided on the suppression member 22.

### Second Embodiment

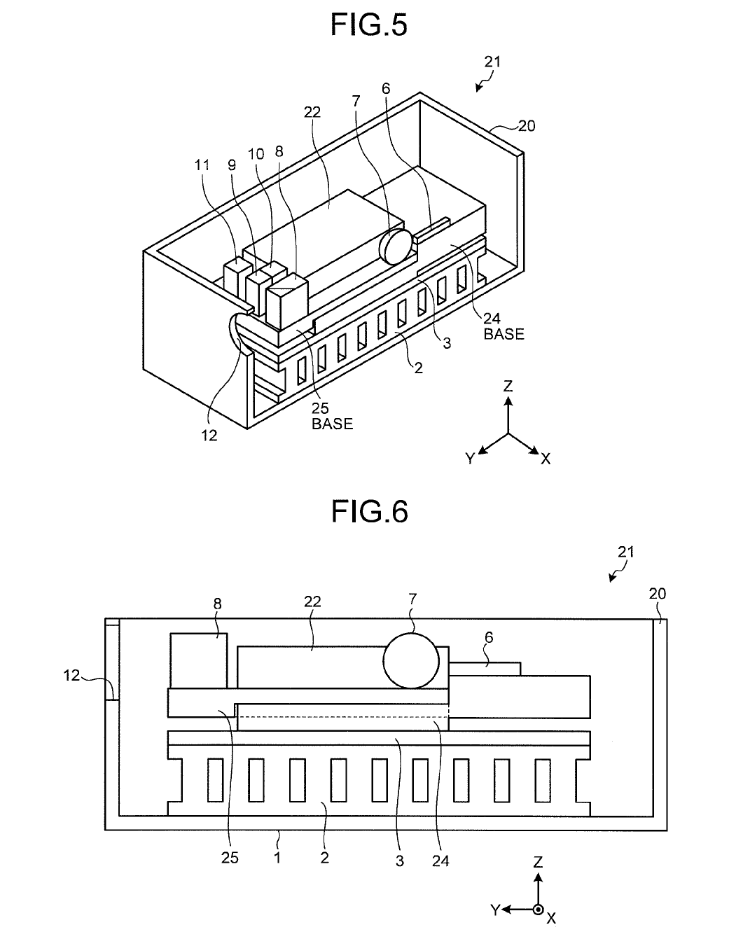

FIG. 5 is a schematic illustrating a longitudinal sectional view of a semiconductor laser module of a second embodiment of the present invention when viewed from a diagonal direction. FIG. 6 is a longitudinal sectional view of the semiconductor laser module illustrated in FIG. 5. In FIGS. 5 and 6, in a semiconductor laser module 21, a base 24 corresponding to the base 4 is bonded to the bonding member 3 at only a nearly central part of the Peltier element 2, and an end side on which the semiconductor laser element 6 is mounted and an end side on which the beam splitter 8 and the etalon 9 are mounted are not bonded to the bonding member 3. Accordingly, a region on which the semiconductor laser element 6 is mounted on the base 24 is formed in a cantilever structure and in a floating state while an end region on which the beam splitter 8 and the etalon 9 are mounted on a base 25 corresponding to the base 5 is also formed in a cantilever structure and in a floating state.

The base 24 has a recessed portion formed thereof while the base 25 has a projected portion formed downward thereof. The recessed portion and the projected portion are fitted together. In this fit structure, the base 24 joints with the base 25 by being slid in a Y direction. Obviously, the fit structure may be formed between the bonding member 3 and the base 24. The fit may be designed as a dovetail groove structure.

In the second embodiment, because the cantilever structure is formed as described above, a warp due to a difference in a linear expansion coefficient between the base 24 and the base 25 does nor occur in the region. In addition, because the bonding part of the Peltier element 2 and the base 24 is limited at only the central part, a warp of the bonding surface of the Peltier element 2 effects only the central part. Therefore, even if a warp occurs in the Peltier element 2, the effect of the warp of the Peltier element 2 to the stacked-plate structure including the bases 24 and 25 can be suppressed to the minimum. In this case, simply linear expansion coefficients between the bases of the stacked-plate structure may be taken into consideration. Particularly in the example, because the end on which the beam splitter 8 and the etalon 9 or the semiconductor laser 6 is mounted is formed in the cantilever structure, and a warp does not occur in the end side, an optical axis shift further hardly occurs.

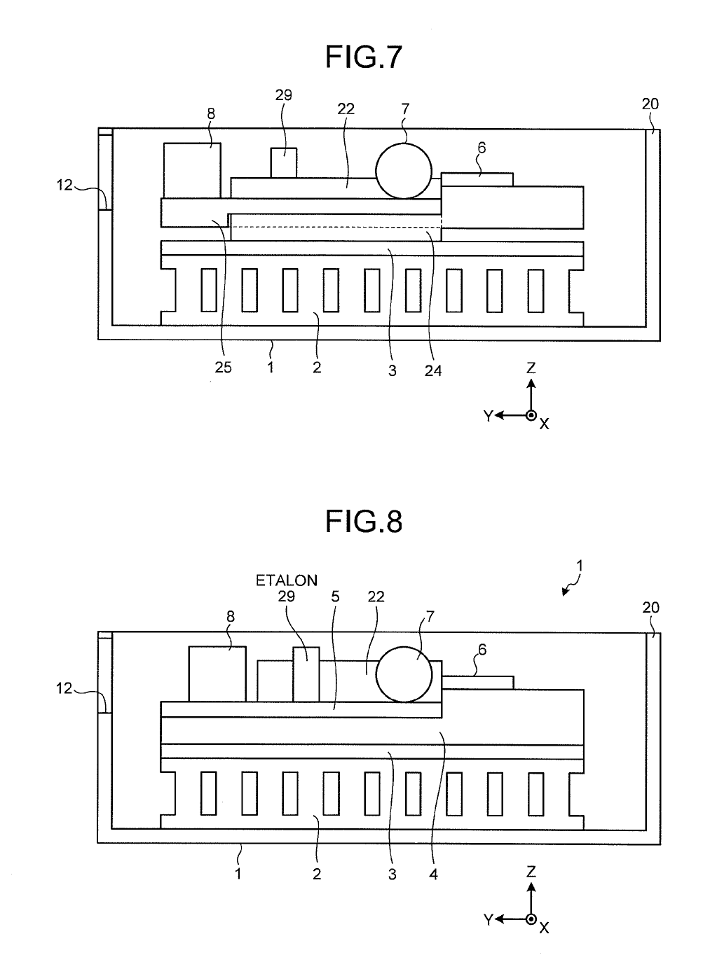

As illustrated in FIG. 7, an optical element such as an etalon 29 may be mounted on the suppression member 22 in the same manner as the first embodiment.

### EXAMPLES

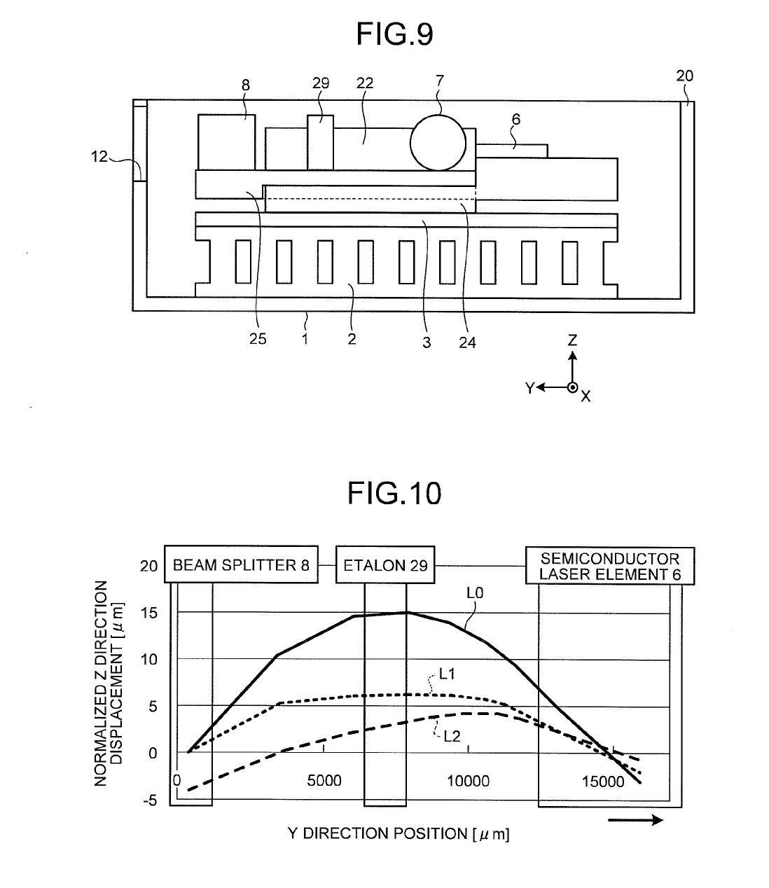

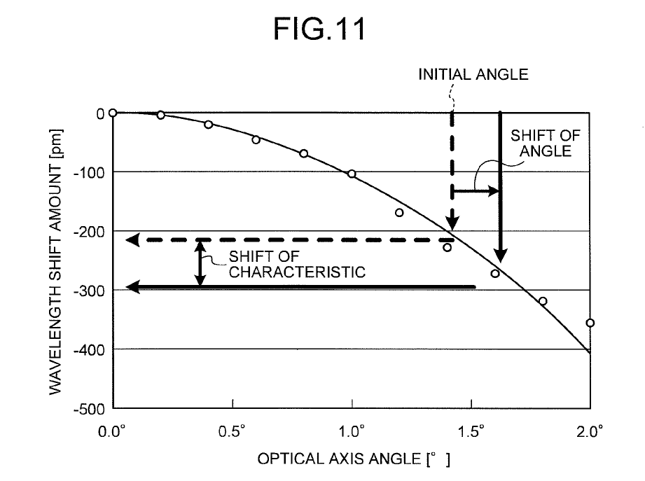

Here, a comparison of the above-described first and the second embodiments and a conventional example is described. FIG. 8 illustrates a structure of a comparative example 1 corresponding to the first embodiment. The etalon 29 is provided at a position between the condensing lens 7 and the beam splitter 8 on the base 5 and apart from an optical axis. FIG. 9 illustrates a structure of a comparative example 2 including a cantilever structure, corresponding to the second embodiment. The etalon 29 is provided at a position between the condensing lens 7 and the beam splitter 8 on the base 25 and apart from an optical axis. In both the comparative examples 1 and 2, on the bases 5 and 25, the suppression member 22 is provided. In other words, in both the comparative examples 1 and 2, a stacked-plate structure composed of platy members of a three-layer structure is formed. As a conventional example, on a base made of a platy member of a single-layer structure, the semiconductor laser element 6, the beam splitter 8, and the etalon 29 are provided.

FIG. 10 is a schematic illustrating a displacement amount in a Z direction with respect to a minus Y direction of a base of each of the comparative examples 1 and 2 corresponding to the first and the second embodiments, and the conventional example. Curves L0, L1, and L2 represent minus Y direction position dependency of a Z direction displacement amount of the conventional example, the comparative example 1, and the comparative example 2, respectively. As illustrated in FIG. 10, in the conventional example, a large Z direction displacement of about 15 μm is produced at the central part. In contrast, in the comparative example 1, a Z direction displacement of about 5 μm is produced at the central part. In the comparative example 2, a Z direction displacement of relatively about 10 μm is produced. As illustrated, the comparative examples 1 and 2 can cause the Z direction displacement amounts to be smaller than that of the conventional example.

While the Y direction angle of the etalon 29 located at the central part is nearly zero in the comparative example 1, in the comparative example 2, the Y direction angle of the etalon 29 located at the central part is nearly the same value as the Y direction angle of the beam splitter 8, and the etalon 29 is slanted in the same direction as the beam splitter 8. In other words, in the comparative example 2, because the displacements of the beam splitter 8 and the etalon 29 have the same gradient, it can be found that a relative displacement amount (relative displacement angle) between the beam splitter 8 and the etalon 29 becomes an extremely small amount.

Specifically, referring to FIG. 10, in the conventional example, the Y direction displacement angle of the beam splitter 8 is 0.19° while the Y direction displacement angle of the etalon 29 is 0.01°. As a result, the Y direction relative displacement angle between the beam splitter 8 and the etalon 29 is 0.18°. In the comparative example 1, the Y direction displacement angle of the beam splitter 8 is 0.09° while the Y direction displacement angle of the etalon 29 is 0.00°. As a result, the Y direction relative displacement angle between the beam splitter 8 and the etalon 29 is 0.09°. Furthermore, in the comparative example 2, the Y direction displacement angle of the beam splitter 8 is 0.07°, while the Y direction displacement angle of the etalon 29 is 0.03°. As a result, the Y direction relative displacement angle between the beam splitter 8 and the etalon 29 is 0.04°. Here, the Y direction displacement angle is a slanted angle with respect to the Y axis, and is made as a result of a displacement of the optical element in the Z direction.

Consequently, in the comparative examples 1 and 2, an occurrence of a relative shift of the optical axis between the beam splitter 8 and the etalon 29 can be reduced. Particularly, in the comparative example 2, the relative optical axis shift can be extremely reduced. As a result, wavelength locking can be performed with high accuracy.

### INDUSTRIAL APPLICABILITY

The semiconductor laser module and the suppression member according to the present invention are applicable for use such as a light source for optical communications.

### REFERENCE SIGNS LIST

1, 21 semiconductor laser module
2 Peltier element
3 bonding member
4, 5, 24, 25 base
6 semiconductor laser element
7 condensing lens
8 beam splitter
9, 29 etalon
10 supporter
11 light detector
12 opening
19 bonding part
20 case
22, 22a suppression member

1-12. (canceled)

13. A semiconductor laser module in which a plurality of optical elements optically coupled with each other are disposed on an upper surface of a temperature control element through at least one base, the semiconductor laser module comprising:
a suppression member that is disposed, in order to suppress a deformation caused by a temperature change of the at least one base, on at least part of a deformation part of the at least one base, and has a linear expansion coefficient having a magnitude compensating for a linear expansion coefficient of the at least one base in order to suppress the deformation of the at least one base.

14. The semiconductor laser module according to claim 13, wherein the at least one base includes a first base on which a semiconductor laser element is mounted, and a second base on which at least one of the optical elements is mounted and that is stacked on the first base, and the suppression member is disposed on a surface of the first base and/or the second base.

15. The semiconductor laser module according to claim 14, wherein a magnitude relationship between a linear expansion coefficient of the first base and a linear expansion coefficient of the second base, and a magnitude relationship between the linear expansion coefficient of the second base and a linear expansion coefficient of the suppression member have a reverse relationship with each other.

16. The semiconductor laser module according to claim 14, wherein a product of the linear expansion coefficient of the first base and a layer thickness of the first base is nearly equal to or smaller than a product of the linear expansion coefficient of the suppression member disposed on the second base and a layer thickness of the suppression member.

17. The semiconductor laser module according to claim 13, wherein the suppression member is disposed on a surface on which the optical elements are absent, and has a shape suppressing the deformation.

18. The semiconductor laser module according to claim 14, wherein an end on which the optical element(s) is (are) fixed of the second base is mounted on the first base as a cantilever structure.

19. A semiconductor laser module in which a plurality of optical elements are disposed on an upper surface of a temperature control element through a plurality of bases, wherein
at least one of the plurality of bases is a suppression layer that has a linear expansion coefficient suppressing a deformation of another base other than the at least one of the plurality of bases in order to suppress the deformation of the other base due to a linear expansion coefficient difference associated with a temperature change of the other base.

20. The semiconductor laser module according to claim 19, wherein, on surfaces of the plurality of bases, suppression members suppressing deformations due to a temperature change of the plurality of bases are disposed.

21. The semiconductor laser module according to claim 18, wherein the temperature control element and a base on the temperature control element come in contact with each other at only around a central part thereof.

22. The semiconductor laser module according to claim 19, wherein the temperature control element and a base on the temperature control element come in contact with each other at only around a central part thereof.

23. The semiconductor laser module according to claim 13, wherein, on an upper surface of the suppression member, an optical element is further disposed.

24. The semiconductor laser module according to claim 19, wherein, on an upper surface of the suppression member, an optical element is further disposed.

25. The semiconductor laser module according to claim 13, wherein, on an upper surface of the suppression member, a heat dissipation structure is provided.

26. The semiconductor laser module according to claim 19, wherein, on an upper surface of the suppression member, a heat dissipation structure is provided.

27. A suppression member suppressing a warp of a base that warps by a temperature change, wherein the suppression member suppresses the warp of the base by compensating a difference in a linear expansion coefficient of the base.
